(19) United States
(12) Patent Application Publication
(10) Pub. No.: US 2022/0316050 A1
(43) Pub. Date: Oct. 6, 2022

(54) PVD THICKNESS CONTROL

(71) Applicant: SMS group GmbH, Düsseldorf (DE)

(72) Inventors: Lutz KÜMMEL, Jüchen (DE); Thomas DAUBE, Duisburg (DE)

(73) Assignee: SMS group GmbH, Düsseldorf (DE)

(21) Appl. No.: 17/606,224

(22) PCT Filed: Apr. 22, 2020
(86) PCT No.: PCT/EP2020/061168

§ 371 Date: Oct. 25, 2021

(30) Foreign Application Priority Data
Apr. 23, 2019 (DE) 10 2019 205 794.2
Jan. 14, 2020 (DE) 10 2020 200 366.1

(51) Int. Cl. C23C 14/54; C23C 14/24

(52) U.S. Cl. CPC C23C 14/545; C23C 14/24

(57) ABSTRACT

A method for coating a metal strip by means of a metallic substrate in a strip coating system, wherein the coating is carried out according to the principle of physical vapor deposition and the layer thickness is set via the parameters of the strip speed and the vaporization rate. It is provided according to the invention that in the event of a layer thickness change and/or a width change of the metal strip, the vaporization rate and the strip speed are changed simultaneously, so that the layer thickness change can be implemented directly independently of the thermal vaporization process.

### FIELD

The present invention relates to a method for coating a metal strip, in particular a steel strip, by means of a metallic substrate, in particular zinc, in a strip coating system, wherein the coating takes place according to the principle of physical vapor deposition (PVD) and the layer thickness is set via the parameters of the strip speed and the vaporization rate.

### BACKGROUND

Methods for coating metallic strips with a passivation layer are known in principle from the prior art.

For example, JPS6296669 discloses a method for coating steel strips with a zinc layer, wherein the temperature of the steel strip is set to a specific temperature range before the coating.

JPS63128168 discloses a method for coating steel strips with a zinc layer, which has improved deep-drawability.

A control unit for a gas phase separator is known from JPH05287528, in order to improve the quality of the deposited layer. In this case, the deposited layer thickness is determined by means of a layer thickness detector and the strip speed is continuously determined by means of a speed detector and sent to the control unit. If, for example, the layer thickness target value is not reached or is exceeded, the strip speed is adjusted accordingly via the control unit so that the deposited layer thickness can be kept constant.

A method for coating steel strips with aluminum is known from JPS6320448, wherein the formation of an AI-Fe alloy layer is prevented by prior formation of an AIN layer. The layer thickness of the AIN layer is set here by adjusting the strip speed.

DE 1 521 573 discloses a control system for continuous strip painting processes in a vacuum, wherein metal vapor is deposited on a surface of a strip in accordance with the strip speed, so that a uniform layer thickness is achieved.

EP 0 176 852 discloses a vacuum coating device for continuously coating a metal strip, in which a control device is provided for changing the width of the metal vapor channel so that metal strips of different widths can be coated with a uniform layer thickness.

Moreover, a method for coating a metal strip is known from Japanese publication JP 2008 138227 A, in which a vaporization rate and a strip speed are changed simultaneously in the event of a speed change of the metal strip to achieve a constant layer thickness of the deposited metal during the startup and during the shutdown of the system.

In a PVD coating process, the desired metallic substrate is vaporized and deposited on a metallic surface, wherein the vaporization usually takes place in a vacuum by means of known techniques. The vaporized metallic substrate is then deposited on the surface of the metal strip.

Since the vaporization process is a thermal process, the adjustment of the vaporization rate in the event of a process change, such as a change in layer thickness and/or a change in width of the metal strip, takes place only slowly, so that a section is formed on the metal strip that does not have the desired layer thickness and therefore does not meet the quality requirements.

### SUMMARY

The present invention is therefore based on the object of providing a method which overcomes the disadvantages of the prior art.

The disclosure further relates to preferred embodiments or refinements of the present invention, the respective features of which can be freely combined with one another within the scope of what is technically meaningful, possibly also beyond the category boundaries of the various claims.

The method is provided for coating a metal strip by means of a metallic substrate in a strip coating system, wherein the coating is carried out according to the principle of physical vapor deposition (PVD) and the layer thickness is set via the parameters of the strip speed and the vaporization rate. According to the invention it is provided that in the event of a change of the desired target layer thickness and/or a width change of a following strip to the preceding metal strip, the vaporization rate and the strip speed are changed simultaneously, so that a change of the layer thickness is directly implementable independently of the thermal vaporization process .

The coating can take place on one side or preferably on both sides, i.e., both the top side and the bottom side of the metal strip are coated.

The present invention is based on the essential finding that the layer thickness change can be set directly on the metal strip independently of the slow thermal changeover process by means of a superimposed speed adjustment. In this way, the formation of larger metal strip sections which do not yet have the desired, newly set layer thickness can be effectively avoided. Furthermore, the adjustment of the vaporization rate is advantageous in order to operate the method or the system at the optimal production speed.

The and/or formulation makes it clear to a person skilled in the art that different embodiment variants can be implemented by means of the method according to the invention.

If, for example, a new layer thickness is to be applied to the metal strip to be coated or to the subsequent metal strip, the vaporization rate is adjusted accordingly. If the layer thickness is reduced, the vaporization rate is reduced; if the layer thickness is increased, it is increased. The slow decrease or increase in the vaporization rate, which lasts for several minutes, is compensated for in this phase by a continuous adjustment in the form of an increase or decrease in the strip speed, so that the layer thickness deposited on the subsequent metal strip immediately corresponds to the desired target layer thickness.

If, for example, the following strip, which is wider or narrower than the preceding metal strip, is to be coated with the same layer thickness, the vaporization rate is adjusted accordingly. If the following strip is narrower, the vaporization rate is reduced. If the following strip is wider, the vaporization rate is increased. The slow decrease or increase in the vaporization rate, which lasts for several minutes, is compensated for in this phase by a continuous adjustment in the form of an increase or decrease in the strip speed, so that the layer thickness deposited on the following strip immediately corresponds to the desired target layer thickness.

In a further embodiment variant according to the invention, the following strip can be made wider than the preceding metal strip, wherein the layer thickness on the following strip is to be greater than on the preceding metal strip. In this case, the vaporization rate is increased accordingly and the strip speed is reduced. The slow decrease or increase in the vaporization rate, which lasts for several minutes, is compensated for in this phase by a continuous decrease in the strip speed, so that the layer thickness deposited on the following strip immediately corresponds to the desired target layer thickness.

In a further embodiment variant according to the invention, the following strip can be made wider than the preceding metal strip, wherein the layer thickness on the following strip is to be less than on the preceding metal strip. In this case, the change in the vaporization rate and the strip speed are dependent on the width change of the following strip and the target layer thickness. If, for example, the vaporization rate and the strip speed are kept constant in this constellation, a smaller layer thickness results automatically due to the larger area to be coated on the following strip. If, for example, only the strip speed is reduced, then, due to the larger area to be coated on the following strip, an even smaller layer thickness automatically results. In principle, however, both the vaporization rate and the strip speed are changed simultaneously in accordance with the desired target specifications in such a way that the layer thickness deposited on the following strip immediately corresponds to the desired target layer thickness.

In a further embodiment variant according to the invention, the following strip can be made narrower than the preceding metal strip, wherein the layer thickness on the following strip is to be greater than on the preceding metal strip. According to the specifications, the vaporization rate and the strip speed are changed simultaneously in such a way that the layer thickness deposited on the following strip immediately corresponds to the desired target layer thickness.

Finally, in a further embodiment variant according to the invention, the following strip can be made narrower than the preceding metal strip, wherein the layer thickness on the following strip is to be less than on the preceding metal strip. According to the specifications, the vaporization rate and the strip speed are changed simultaneously in such a way that the layer thickness deposited on the following strip immediately corresponds to the desired target layer thickness.

In a preferred embodiment variant, the vaporization rate and the strip speed are changed together at fixed time intervals, so that the two parameters can be matched with one another in a particularly fine manner. In principle, the smaller the time interval selected, the more precisely a change of the desired target layer thickness and/or a width change of the following strip to the preceding metal strip can be carried out.

The change of the desired target layer thickness and/or the width change of the following strip to the preceding metal strip preferably takes place via value pairs of vaporization rate and strip speed per time interval, which are particularly preferably based on historical data and/or a model relationship. In the case of known changes in the area to be coated and/or in the layer thickness to be coated, the speed adjustment can be precontrolled accordingly per unit of time in order to achieve an immediate adjustment.

The metal strip is preferably a steel strip. The metallic substrate preferably comprises zinc, so that a pure zinc layer is formed as the resulting coating.

In a further preferred embodiment variant, the metallic substrate can also have contents of magnesium, aluminum, iron, or silicon, so that a zinc alloy layer is formed as the resulting coating.

In a particularly preferred embodiment variant, the layer thickness change and/or the width change of the metal strip is at least 10%, more preferably 15%, even more preferably 20%, and most preferably 25%.

To determine the layer thickness, a layer thickness measuring device is preferably used that is arranged downstream of the coating device. Due to the downstream layer thickness measuring device, the layer thickness can be regulated by adjusting the strip speed and the vaporization rate.

### BRIEF DESCRIPTION OF THE FIGURES

Further advantages and features of the method according to the invention result from the following exemplary embodiments, which are explained in more detail with reference to drawings. In the FIGURE:

FIG. 1 shows a schematically simplified side view of an embodiment variant of the system according to the invention.

FIG. 1 shows an embodiment variant of a system 1 in a schematically greatly simplified side view.

### DETAILED DESCRIPTION

The system 1 is suitable for carrying out the method according to the invention in which a metal strip 10 is carried out by means of a metallic substrate 12 according to the principle of physical vapor deposition (PVD), wherein the layer thickness is set via the parameters of the strip speed and the vaporization rate according to the following formula.

$${d}_{Me} = \frac{E ( b , v , t ) * S ( T )}{b * {v}_{strip}}$$

where

| | | |
|---|---|---|
| vaporization rate | S(T) | [g/s] |
| width | b | [m] |
| strip speed | vₛₜᵣᵢₚ | [m/s] |
| efficiency | E(b, v, t) | [—] |
| layer thickness | d_{Me} | [g/m²] |

The system 1 initially comprises a continuous treatment line 2 in which the metal strip 10 is initially unwound by a first reel device 11 and is rewound again at the end of the treatment line 2 by a second reel device 13. Within the treatment line 2, the metal strip 10 is moved in a direction of movement of the arrow 3 and passes through several stations in the process.

In the embodiment variant shown here, the system 1 comprises a pickling device 14 arranged in the treatment line 2 and a coating device 16 arranged downstream.

In the pickling device 14, the surfaces of the metal strip 10, for example a steel strip, are prepared so that they can then be coated in the coating device 16.

In the coating device 16, the metal strip 10 is then coated on at least one side, preferably on both sides, with the metallic substrate 12, for example a zinc layer, according to the principle of physical vapor deposition (PVD). The layer thickness is settable for this purpose via the parameters of the strip speed and the vaporization rate according to the above formula.

If, for example, a different layer thickness is to be set, the strip speed can be adjusted by rearranging the above formula. Therefore:

$${v}_{strip} = \frac{E ( b , v , t ) * S ( T )}{b * {d}_{Me}}$$

The same relationship also applies to a width change or to a combination.

If all process settings, such as the vaporization rate and the width, remain unchanged, then only the following applies:

$${v}_{strip , new} = {v}_{strip , old} * \frac{{d}_{Me , new}}{{d}_{Me , old}}$$

If all process settings, such as the vaporization rate and the layer thickness, remain unchanged, then only the following applies:

$${v}_{strip , new} = {v}_{strip , old} * \frac{{b}_{new}}{{b}_{old}}$$

After this, changes in layer thickness or width can be adjusted up to a specific level without changing the vaporization rate.

However, the rapidity of the changeover process is limited by a speed change per unit of time. If greater layer thickness and/or width changes have to be implemented, the vaporization rate has to be adjusted.

It is therefore provided in the method according to the invention that in the event of a change of the desired target layer thickness and/or a width change of the following strip to the preceding metal strip 10, the vaporization rate and the strip speed are changed simultaneously, so that the layer thickness change can be implemented directly independently of the thermal vaporization process. In other words, the vaporization rate can be predictively adjusted when changing the layer thickness.

For this purpose, the system 1 comprises a control unit 18, which, in the event of a change of the desired target layer thickness and/or a width change of the following strip to the preceding metal strip 10, changes the vaporization rate and the strip speed, so that the change of the layer thickness can be implemented directly independently of the thermal vaporization process. In the embodiment variant shown here, the control unit 18 is EDP-supported and additionally comprises a storage unit 19 in which value pairs of vaporization rates and strip speeds are stored per time interval. These can be based on past data or models, for example.

If, for example, a new, 25% lesser layer thickness is to be applied to the metal strip 10, the vaporization rate is reduced via the control unit 18. The slow decrease in the vaporization rate, which lasts for several minutes, is compensated for in this phase by a continuous adjustment in the form of an increase in the strip speed on the basis of the value pairs, so that the layer thickness deposited on the subsequent metal strip immediately corresponds to the desired target layer thickness.

Since the efficiency can also change, this may have to be taken into consideration. Therefore, a layer thickness measuring device 20 is additionally arranged in the treatment line 2 downstream of the coating device 16, by means of which the coating is checked.

A correction value can then be determined and adapted using this measured value. The following applies:

$$C = \frac{{d}_{Me , measured}}{{d}_{Me , target}}$$

The above formula can then be rewritten as:

$${v}_{strip} = \frac{C * S ( T )}{b * {d}_{Me}}$$

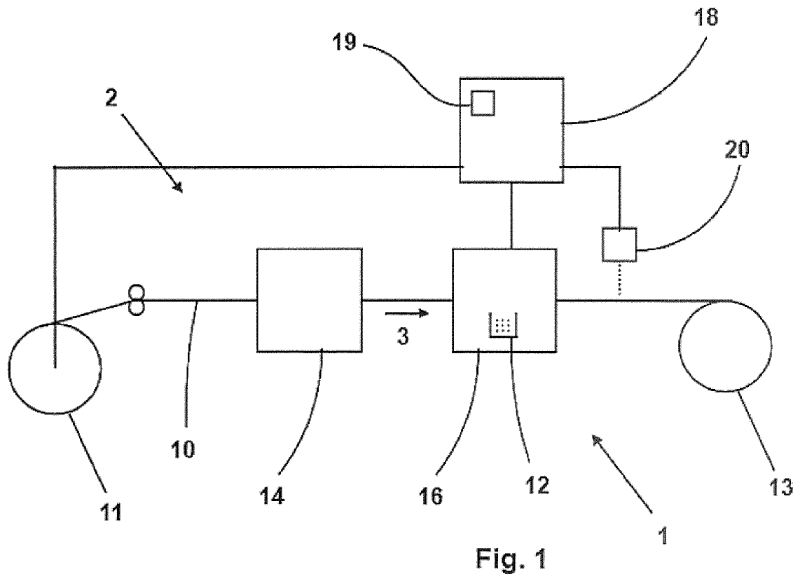

As can be seen in FIG. 1, the coating thickness measuring device 20 is connected to the control unit 18 so that if predetermined values are not reached or are exceeded, the coating can be readjusted in accordance with the mathematical relationship shown in order to implement a uniform coating.

1-9. (canceled)

10. A method for coating a metal strip by means of a metallic substrate in a strip coating system, wherein the coating is carried out according to the principle of physical vapor deposition and the layer thickness is set via the parameters of the strip speed and the vaporization rate, wherein
in the event of a change of the desired target layer thickness and/or a width change of a following strip to the preceding metal strip, the vaporization rate and the strip speed are changed simultaneously, so that a change of the layer thickness can be implemented directly independently of the thermal vaporization process.

11. The method as claimed in claim 10, wherein the vaporization rate and the strip speed are changed at fixed time intervals.

12. The method as claimed in claim 10, wherein the change of the desired target layer thickness and/or the width change of the following strip to the preceding metal strip take place via value pairs of vaporization rate and strip speed per time interval.

13. The method as claimed in claim 12, wherein the value pairs are based on historical data and/or a model relationship.

14. The method as claimed in claim 10, wherein the metal strip comprises a steel strip and the metallic substrate comprises zinc.

15. The method as claimed in claim 10, wherein the change of the desired target layer thickness and/or the width change of the following strip to the preceding metal strip is at least 10%, preferably 15%, more preferably 20%, and most preferably 25%.

16. The method as claimed in claim 10, wherein a layer thickness measuring device is used to determine the layer thickness.
